(19) United States
(12) Patent Application Publication
(10) Pub. No.: US 2025/0286513 A1
(43) Pub. Date: Sep. 11, 2025

(54) VOLTAGE REGULATOR TO ENABLE REDUCED MEMORY EFFECTS IN POWER AMPLIFIER

(71) Applicant: Silicon Laboratories Inc., Austin, TX (US)

(72) Inventor: Aslamali A. Rafi, Austin, TX (US)

(21) Appl. No.: 18/601,408

(22) Filed: Mar. 11, 2024

(51) Int. Cl. H03F 1/02; H03F 1/32; H03F 3/24; H03F 3/45

(52) U.S. Cl. CPC H03F 1/0238; H03F 1/3241; H03F 3/245; H03F 3/45475; H03F 2200/102; H03F 2201/3209

(57) ABSTRACT

In one example, an apparatus includes: an operational amplifier (opamp) to amplify a difference between a reference voltage and a feedback voltage and output a bias signal based on the difference; a replica device coupled to the opamp, the replica device having a gate terminal to receive the bias signal; and an output stage coupled to the replica device and to output a regulated voltage, the output stage having a pass device and a plurality of feedback devices coupled to the pass device. A selected number of the plurality of feedback devices can be enabled based at least in part on an output power level of a power amplifier that is to receive the regulated voltage.

### BACKGROUND

Power amplifiers (PAs) often need to operate from power supplies that have a wide output voltage range. For example, the power supply's output voltage could range from 2.7 volts (V) to 3.6V or higher. Furthermore, PAs often operate at the limits of semiconductor process technology in terms of the tolerable voltage on transistors of the PA. The higher end of the supply voltage range can cause reliability concerns for these transistors, and a linear regulator is typically used to limit the voltage.

But for PAs processing non-constant envelope signals like orthogonal frequency division multiplexing (OFDM) signals (as per a given IEEE 802.11 a/ax/n/ac standard), the regulator can significantly limit error vector magnitude (EVM) achievable by causing what are known as “memory effects”. Such memory effects occur when a current output of the PA depends on past inputs to the PA. Regulator bandwidth plays a crucial role, since when a regulator has slow settling behavior, the PA's current transfer characteristic depends on the past input.

Furthermore, many PAs draw current that can change by a huge factor (e.g., 60×) across a power control range (for example, from 20 decibel-milliwatts (dBm) to −15 dBm). Conventional regulator topologies can suffer greatly from memory effects and limit the error vector magnitude (EVM) achievable. Typical solutions use digital compensation to correct for these memory effects, but such compensation can be very complex, and does not improve EVM adequately.

### SUMMARY OF THE INVENTION

In one implementation, an apparatus includes: an operational amplifier (opamp) to amplify a difference between a reference voltage and a feedback voltage and output a bias signal based on the difference; a replica device coupled to the opamp, the replica device having a gate terminal to receive the bias signal; and an output stage coupled to the replica device and to output a regulated voltage, the output stage comprising a pass device and a plurality of feedback devices coupled to the pass device. A selected number of the plurality of feedback devices can be enabled based at least in part on an output power level of a power amplifier, the power amplifier to receive the regulated voltage.

In one implementation, the power amplifier comprises a plurality of slices, the selected number of the plurality of feedback devices based at least in part on a number of the plurality of slices to be enabled. The apparatus may include a bias circuit comprising the opamp and the replica device, the replica device to replicate a feedback device of the plurality of feedback devices. The replica device may have a first terminal coupled to a voltage divider, the voltage divider to provide the feedback voltage to the opamp, and a third terminal coupled to a reference voltage node via a resistor.

In one implementation, the apparatus further includes a controller to enable the selected number of the plurality of feedback devices based at least in part on a modulation coding scheme (MCS) index for a wireless transmission by the power amplifier. The controller may include a lookup table, and the controller is to obtain a control code based at least in part on the output power level and send the control code to selectively enable or disable each of the plurality of feedback devices.

In an embodiment, each of the plurality of feedback devices comprises: a first terminal coupled to the pass device; a gate terminal coupled to receive the bias signal; and a third terminal coupled to a first switch of a plurality of first switches, the first switch to enable the corresponding feedback device based on a bit of the control code. The output stage may further include: a first current source coupled to the pass device; a third device coupled to the first current source; and a second current source coupled to the third device, the third device switchably coupled to a selected one or more of the plurality of feedback devices. Each of the plurality of first switches is further coupled, at an inter-switch node, to a second switch of a plurality of second switches, where the third device is coupled to the inter-switch node. Each of the plurality of second switches is further coupled to a third current source of a plurality of third current sources.

In an implementation, the apparatus comprises a voltage regulator for the power amplifier, the voltage regulator to provide analog memory effect compensation, the pass device coupled to the output node without a compensation capacitor. The power amplifier may be configured to operate without dynamic digital pre-distortion.

In another aspect, a method includes: determining, in a controller of a wireless device, an output power level for a wireless transmission to be output via a power amplifier of the wireless device; based at least in part on the output power level, determining a number of output stage feedback slices of a voltage regulator to be enabled; and configuring the number of output stage feedback slices of the voltage regulator to couple to an output node of the voltage regulator, the output node to provide a regulated voltage to the power amplifier.

In an implementation, the method further comprises causing a corresponding current source of each of the number of output stage feedback slices to be coupled to the output node of the voltage regulator to provide a load current for the power amplifier. The method may also include: amplifying, in an opamp of the voltage regulator, a difference between a feedback voltage and a reference voltage; outputting a bias signal based on the difference; and providing the bias signal to a corresponding feedback device of each of the number of output stage feedback slices.

In an implementation, the method further comprises providing the regulated voltage to the power amplifier with a bandwidth sufficient to operate the power amplifier without digital memory effect compensation.

In yet another aspect, a system includes: a digital circuit to generate a digital message; a digital-to-analog converter (DAC) to convert the digital message to an analog signal; a mixer to upconvert the analog signal to a radio frequency (RF) signal; a power amplifier coupled to the mixer to amplify the RF signal and output an amplified RF signal, the power amplifier comprising a plurality of slices to be individually controlled to output the amplified RF signal at a selected power level; and a voltage regulator coupled to the power amplifier. The voltage regulator may be configured to provide a regulated voltage to the power amplifier at a current level sufficient for the selected power level.

In an implementation, the voltage regulator may include: a bias circuit comprising an opamp to amplify a difference between a reference voltage and a feedback voltage and output a bias signal based on the difference; and an output stage coupled to the bias circuit and to output the regulated voltage, the output stage comprising a pass device and a plurality of feedback devices coupled to the pass device, where a selected number of the plurality of feedback devices are to be enabled based at least in part on the selected power level and to receive the bias signal.

In an implementation, the system further comprises a controller coupled to the voltage regulator, where the controller is to provide, based at least in part on the selected power level, a control code to cause the selected number of the plurality of feedback devices to be enabled. The power amplifier may be a multi-slice power amplifier to operate with an error vector magnitude of at least minus 45 decibels, and where the power amplifier is to operate without dynamic digital memory effect compensation. The voltage regulator is to receive a supply voltage, where when the supply voltage is less than a threshold, the voltage regulator is to operate in a bypass mode in which the output stage is to operate as a low resistance switch to pass the supply voltage.

### BRIEF DESCRIPTION OF THE DRAWINGS

FIG. 1 is a block diagram of an apparatus in accordance with an embodiment.

FIG. 2 is a schematic diagram of a voltage regulator in accordance with an embodiment.

FIG. 3 is a flow diagram of a method in accordance with an embodiment.

FIG. 4 is a block diagram of a representative integrated circuit that incorporates an embodiment.

FIG. 5 is a high level diagram of a network in accordance with an embodiment.

### DETAILED DESCRIPTION

In various embodiments a voltage regulator is tightly coupled with a PA to provide a regulated voltage at a high bandwidth and a substantially steady value. In this way, the PA can operate with minimal or no memory effect. And as a result, the PA can be designed with less complexity since dynamic digital memory effect compensation can be avoided. Instead, a minimal amount of static non-linearity of the PA can be corrected digitally, e.g., using a lookup table, resulting in a PA that has significantly reduced dynamic non-linearity. This digital compensation may be implemented by providing feedback from the PA output to digital circuitry, which may access a given entry of the lookup table based on the feedback signal level (where the receiver is assumed to be linear and introduce negligible distortion). The digital value of this entry then may be used to provide the digital compensation, applied as pre-distortion (amplitude and phase) to an input signal of the transmit chain. In other words, the input signal is pre-distorted when it is a digital signal, such that the non-linearity introduced by the PA is cancelled by the pre-distortion introduced by the LUT. Note that with embodiments a simply static pre-distortion may be performed, avoiding the need for dynamic digital pre-distortion. Still further, with embodiments having a voltage regulator configured as described herein, the PA can operate with a low EVM, e.g., at approximately minus 45 dB.

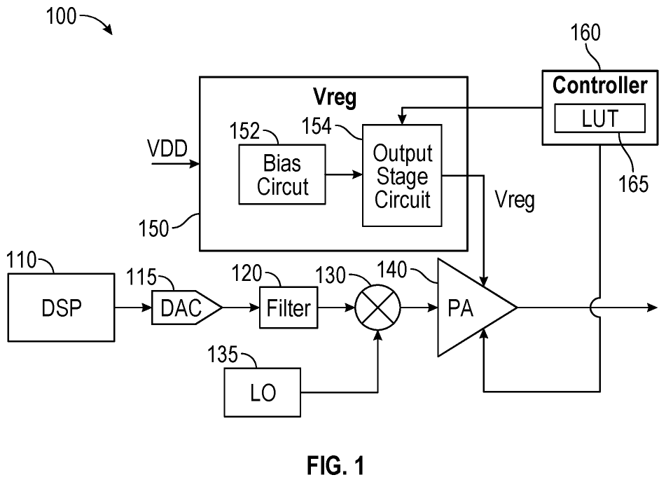

Referring now to FIG. 1, shown is a block diagram of an apparatus in accordance with an embodiment. As shown in FIG. 1, apparatus 100 may be any type of wireless communication device, ranging from smartphone, tablet computer, personal computer, Internet of Things (IoT) device and so forth. In the embodiment of FIG. 1, only a portion of apparatus 100 is illustrated, namely a transmit portion such as may be part of a multi-protocol wireless transceiver.

As shown, digital information is processed in a digital signal processor (DSP) 110 and provided in digital form to a digital-to-analog converter (DAC) 115, which converts the digital signals to an analog stream. The resulting analog signals are provided to a filter 120, which filters the information within the analog stream. The filtered analog signals are provided to a mixer 130, which operates to upconvert the analog stream from baseband to a radio frequency (RF) signal using a mixing signal received from a local oscillator (LO) 135. The resulting RF signals output from mixer 130 are provided to a PA 140.

PA 140 amplifies the RF signals and sends them along for transmission via an antenna (not shown for ease of illustration in FIG. 1). In embodiments herein, PA 140 may be implemented as a so-called sliced power amplifier. This sliced PA has a plurality of units or slices that can be independently controlled to output an amplified RF signal with a wide power control range (e.g., from 20 dBm to minus 15 dBm).

As further illustrated in FIG. 1, PA 140 is powered by a regulated voltage output from a voltage regulator 150. With embodiments, voltage regulator 150 operates at a high bandwidth to provide the regulated voltage at a substantially steady level, particularly in light of the widely changing output power levels generated by power amplifier 140.

As shown, voltage regulator 150 includes a bias circuit 152. As will be described herein, bias circuit 152 is configured to generate a bias voltage that is provided to an output stage circuit 154. Bias circuit 152 includes replica circuitry that replicates circuitry within output stage circuit 154. By providing this matching topology between circuitry within bias circuit 152 and output stage circuit 154, improved regulation can be realized. As will be further described, output stage circuit 154 includes multiple feedback devices included within so-called feedback stage slices that can be individually controlled to be enabled or disabled.

As further illustrated in FIG. 1, a controller 160 is present. In various embodiments, controller 160 may be implemented as a microcontroller or other programmable circuitry. In embodiments, controller 160 may be a standalone controller to control radio operations within apparatus 100. To this end, controller 160 may determine an appropriate modulation scheme for a particular wireless communication protocol and a communicating partner.

Based at least on these parameters, controller 160 is configured to determine an appropriate modulation coding scheme (MCS) index for use in the transmission. From this MCS index and other information including a range to a communicating partner, controller 160 may determine an output power level to be generated within PA 140. To effect this output power level, controller 160 causes one or more slices of PA 140 to be enabled.

In addition, controller 160 may determine, based at least in part on the number of slices of PA 140 to be enabled, a number of feedback devices of output stage circuit 154 to be enabled to provide sufficient current to PA 140. To this end, controller 160 may include a lookup table storage 165 to store configuration settings. In an embodiment, these configuration settings include digital control words to control enabling/disabling of feedback slices of output stage circuit 154, based at least in part on a determined current consumption level and/or a number of active PA slices.

A selected digital control word is provided to output stage circuit 154 to cause a given number of the feedback devices of output stage circuit 154 to be enabled. Although embodiments are not limited in this regard, in one example there can be between 1 and 63 feedback slices within output stage circuit 154. These feedback slices may be binary weighted and controlled by the digital control word, which may be implemented as a binary feedback control word that is roughly proportional to a square root of the PA current.

Referring now to Table 1, shown is an example of representative entries of a lookup table in accordance with an embodiment. As shown in Table 1, based on a given load current, a selected number of feedback slices can be enabled to provide the right amount feedback gain so as to maximize the bandwidth of the regulator. In the example of Table 1, the digital control code may be implemented with 6 bits.

TABLE 1

| | Number of Feedback Slices |
|---|---|
| | (6 bits → 0:63) (Decimal |
| ILOAD | Code) |

| | | |
|---|---|---|
| 200 | mA | 48 |
| 100 | mA | 33 |
| 50 | mA | 24 |
| 25 | mA | 17 |
| 12.5 | mA | 12 |

Although shown at this high level in the embodiment of FIG. 1, understand that many variations and alternatives are possible.

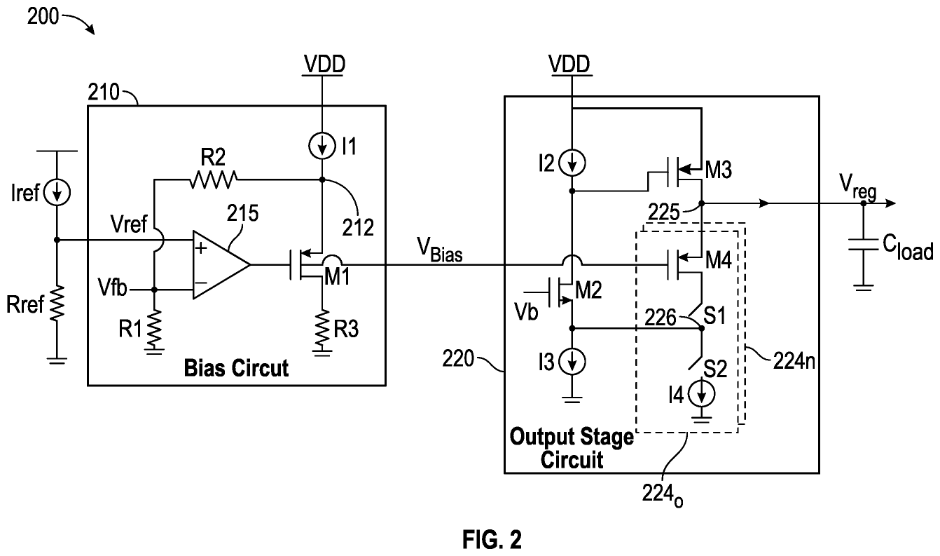

Referring now to FIG. 2, shown is a schematic diagram of a voltage regulator in accordance with an embodiment. As shown in FIG. 2, voltage regulator 200 is implemented as an integrated voltage regulator, in that it is integrated in a single semiconductor die along with circuitry that it powers, namely, a PA. Understand of course that voltage regulator 200 may be used to provide a regulated voltage to other circuitry also.

As illustrated, voltage regulator 200 includes a bias circuit 210 configured to generate a bias voltage (V_{BIAS}), which it provides to an output stage circuit 220. Bias circuit 210 includes an operational amplifier (opamp) 215 that amplifies the difference between a reference voltage (V_{REF}) (generated via a current source Iref coupled to a reference resistor Rref) and a feedback voltage (V_{FB}), created by a voltage divider formed of resistors R2 and R1. The reference voltage may be set at a given voltage level depending on the desired regulated voltage. As one example implementation, V_{REF} may be set at 0.5 volts. This amplified difference signal is used as a gate signal for various transistors as will be described herein.

In an embodiment, resistors R2 and R1 may be implemented with the same instance of a resistor with scaled values. Although embodiments are not limited in this regard, in one example, R2 may have a resistance of 2× (R1). And the values of resistors R1 and R2 can be programmably controlled based on the desired regulated voltage. By using these feedback resistors having a common design, the current through a transistor that generates the bias voltage is not a function of trim settings.

Opamp 215 thus generates a gate signal for a first metal oxide semiconductor field effect transistor (MOSFET) M1. In the embodiment shown, MOSFET M1 is implemented as a P-channel (PMOS) device. As shown, PMOS M1 has a source terminal that couples to a current source I1 at a node 212 (in turn coupled to a supply voltage (VDD) at a supply voltage node) and a drain terminal that couples to a reference voltage node (e.g., a ground node) via a resistor R3. Note that PMOS M1 is implemented as a replica circuit in that it is structurally arranged as a replica of a corresponding feedback device within output stage circuit 220 (e.g., having the same or substantially similar terminal voltages).

With a replica biasing scheme as in FIG. 2, the source terminal of PMOS M1 coupled to node 212 is at a voltage of Vreg and its gate terminal is at Vreg−Vgs_M1, which is Vbias. When output stage circuit 220 is biased with this Vbias, the source terminal of a PMOS device M4 coupled to an output node 225 is at Vreg because M4 is designed to match M1.

Opamp 215 thus amplifies the difference between the reference voltage and the feedback voltage to ultimately generate a replica of the regulated voltage Vreg at the source terminal of PMOS M1 (at node 212).

Bias circuit 210 thus is configured to generate the bias voltage for output stage circuit 220 with low systematic offset. A key advantage of biasing output stage circuit 220 in this way is the operation of the regulator when Vdd drops below the voltage where all devices (current source I1 and MOSFET M3 in particular) are in saturation. As Vdd drops, it is highly desirable to maintain a low output impedance of output stage circuit 220 to reduce memory effects in the PA. With the biasing scheme of bias circuit 210, the gate terminal of MOSFET M1 rises to a voltage near VDD as VDD falls. This is because Vfb drops with VDD and so becomes lower than Vref. Opamp 215 amplifies this difference with its inherent high gain and causes the gate voltage of PMOS M1 to rise to near VDD. This causes PMOS M4 of output stage circuit 220 to turn off. As a result, the current of current source I3 is forced to flow through MOSFET M2 (an N-channel (NMOS) device). But since I3 is greater than I2, this is not sustainable and so I3 ends up pulling the gate voltage of MOSFET M3 to ground. With its gate voltage at ground, MOSFET M3 operates as a voltage switch, providing a very low output impedance to the power amplifier, thereby reducing memory effects. In this way, bias circuit 210 enables a quick transition of voltage regulator 200 into a bypass mode when the power supply voltage (VDD) drops below a threshold. For example in one implementation, when VDD drops below a threshold level of 3.1 V, voltage regulator 200 enters into this bypass mode in which the output impedance is less than 0.15 Ohms, and the supply voltage goes straight to output through pass device M3, which acts like a switch.

Still referring to FIG. 2, output stage circuit 220 includes NMOS M2. As shown, NMOS M2 is coupled to receive a locally generated bias voltage, VB, at a gate terminal. As illustrated, NMOS M2 has a drain terminal coupled to a current source I2 and a source terminal coupled to another current source I3. (Note that current source I2 couples to the supply voltage node and in turn current source I3 couples to the reference voltage node.)

As further shown, output stage circuit 220 includes PMOS M3, which acts as a pass device and has a drain terminal to pass the regulated voltage (Vreg) at output node 225. PMOS M3 has a source terminal coupled to the supply voltage node, and a gate terminal coupled to current source I2 and the drain terminal of NMOS M2.

As further shown, the drain terminal of PMOS M3 also couples to a plurality of feedback devices M4, implemented as PMOS devices. More specifically, output stage circuit 220 includes a plurality of feedback slices 224_{0-N}, each of which couples between output node 225 (and thus the drain terminal of PMOS M3) and the ground node. In one or more embodiments, PMOS M3 may be implemented with a much larger structure than feedback devices M4. In a particular implementation, PMOS M3 may be a PMOS device that is approximately 200 times wider than the full number of feedback devices M4.

FIG. 2 shows details of a representative feedback slice 224₀. As shown, feedback slice 224₀ includes PMOS M4 having a source terminal coupled to output node 225, a gate terminal coupled to receive the bias voltage, Vbias (which is implemented as the amplified difference signal output from opamp 215), and a drain terminal that couples to a current source I4. Note the presence of two switches, S1 and S2, that couple between the drain terminal and current source I4. More specifically, switch S1 directly couples the drain terminal to an inter-device node 226, and switch S2 couples between inter-device node 226 and current source I4. In an embodiment, switches S1 and S2 may be controlled by the same control signal, which may be a bit of a control word (which may be received from a controller, not shown in FIG. 2). When closed, these switches enable the corresponding feedback stage slice 224, providing a variable feedback gain as the current through the regulator changes.

Replica device M1 of bias circuit 210 acts as a replica with respect to feedback device M4. As shown, both of these devices receive at a gate terminal the same output signal from opamp 215, and replica device M1 includes similarly coupled source drain and gate terminals as feedback device M4. And both are implemented as PMOS devices, and can be both built of the same unit transistor having the same finger width and length. However, the number of fingers in MOSFET M4 is scaled with respect to the number of fingers in MOSFET M1 in proportion to the currents through them. In one embodiment, MOSFET M1 carries a current of 100 uA with a finger width of 2.5 um, length of 270 nm and 8 fingers. On the other hand, MOSFET M4 is realized as a programmable (e.g., up to 63) units of finger width 2.5 um, length of 270 nm and 2 fingers carrying a current of 25 uA per unit.

Without an embodiment, a large explicit compensating capacitance may need to be present (and would be coupled between the gate and drain terminals of PMOS M3). Such arrangement would create a significantly slower voltage regulator as compared to embodiments. And such regulator having an explicit and large compensating capacitor would cause a power amplifier to suffer from much worse memory effects.

Instead with embodiments having the arrangement of sliced feedback devices M4 (more generally an output stage having a plurality of feedback slices) that are individually controlled to be enabled/disabled, an explicit capacitor is not needed between gate and drain terminals of PMOS M3. And a unity gain frequency (which is based on a transconductance of PMOS M4 to capacitance (gate-to-drain) of PMOS M3 (gm_M4/Cgd_M3)) reduces as the number of enabled PMOS M4 slices reduces. Similarly, a second pole frequency (which is set by the transconductance of PMOS M3 to load capacitance (gm_M3/Cload)) also reduces as the number of enabled PMOS M4 slices reduces. Thus with an arrangement as in FIG. 2, phase margin is kept roughly constant as PA slices are reduced. Also, voltage regulator 200 can be compensated by just using the parasitic capacitance inherent in PMOS M3. Also with an embodiment as in FIG. 2, a fastest possible regulator is realized, leading to lowest memory effects for a coupled PA for a given device type/technology, since there is no explicit compensating capacitance and inherent device parasitics are used.

In an embodiment, voltage regulator 200 overcomes the problem of memory effects sufficiently, even for large signal bandwidths like 80 MHz. Still further, embodiments can achieve an EVM floor of less than −45 dB, which is more than adequate even high MCS schemes like MCS9 (EVM required is 32 dB as per an 802.11ax standard) and over a wide output power range of the PA.

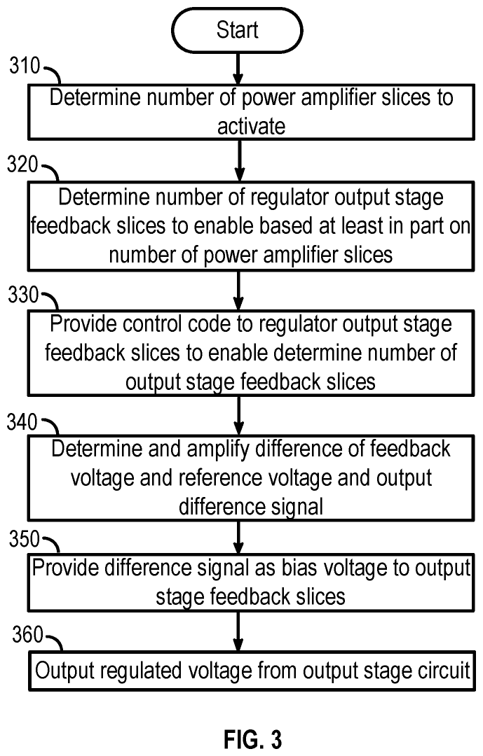

Referring now to FIG. 3, shown is a flow diagram of a method in accordance with an embodiment. As shown in FIG. 3, method 300 is a method for controlling a voltage regulator and an associated power amplifier in accordance with an embodiment. As such, method 300 may be performed at least in part by a controller, such as a microcontroller that configures the voltage regulator and PA based on at least in part on given modulation scheme, including MCS index and a given power level output power level. To this end, method 300 may be executed by the controller, which may execute instructions stored in a non-transitory storage medium.

As illustrated, method 300 begins by determining a number of power amplifier slices to activate (block 310). This determination may be based at least in part on a given output power level, and may be made by reference to a lookup table that associates a given number of power amplifier slices for a determined output power level. Next at block 320, a number of regulator feedback slices to be enabled may be determined. This determination may be based at least in part on the number of PA slices to be enabled. The controller may reference another lookup table that stores entries that include a control code to enable a given number of output stage slices. As discussed above, this control code may be used to control switches that enable given feedback devices to be enabled/disabled.

Next at block 330, the control code is provided to the regulator feedback slices to enable the determined number of them to be enabled, e.g., by closing one or more switches in each of the feedback slices selected to be enabled to cause a coupled current source to provide current through a corresponding feedback device to an output node.

Still with reference to FIG. 3, at block 340 a difference between a feedback voltage and a reference voltage is determined and amplified (e.g., via an opamp of the bias circuit) to cause output of a difference signal. In an embodiment, this feedback voltage may be obtained from a voltage divider. The amplified difference signal may act as a bias voltage that is provided to a gate terminal of the feedback devices, such as shown above in FIG. 2 (block 350).

By controlling a regulator as described herein, a regulated voltage is output from the output stage circuit (block 360) with a sufficient amount of current to enable the PA to transmit at the desired output power level. Although shown at this high level in the embodiment of FIG. 3, understand that many variations and alternatives are possible.

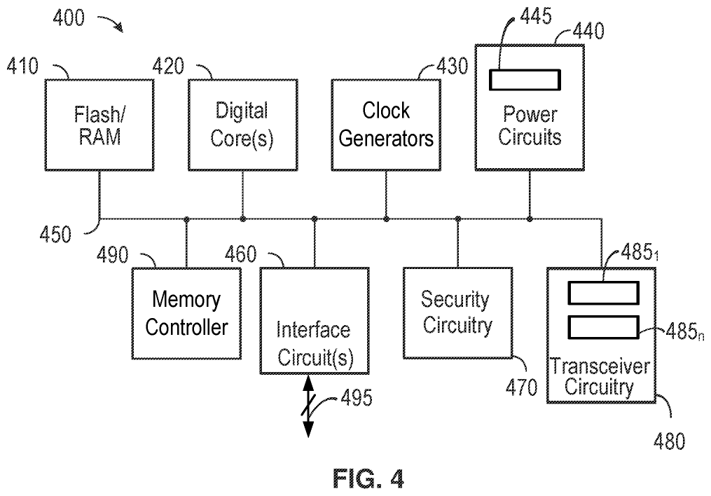

Referring now to FIG. 4, shown is a block diagram of a representative integrated circuit 400 that includes a voltage regulator to provide a regulated voltage to a PA in a manner to reduce memory effect in the PA, as described herein. In the embodiment shown in FIG. 4, integrated circuit 400 may be, e.g., a dual mode wireless transceiver that may operate according to one or more wireless protocols (e.g., WLAN and Bluetooth, among others) or other device that can be used in a variety of use cases. In one or more embodiments, the circuitry of integrated circuit 400 shown in FIG. 4 may be implemented on a single semiconductor die.

Integrated circuit 400 may be included in a range of devices including a variety of stations, including smartphones, wearables, smart home devices, IoT devices, other consumer devices, or industrial, scientific, and medical (ISM) devices, among others.

In the embodiment shown, integrated circuit 400 includes a memory system 410 which in an embodiment may include volatile storage, such as RAM and non-volatile memory as a flash memory. The flash memory is a non-transitory storage medium that can store instructions and data. Such non-volatile memory may store instructions, including instructions for determining an appropriate number of feedback devices of an output stage circuit of a voltage regulator, as described herein. As further shown integrated circuit 400 also may include a memory controller 490.

Memory system 410 couples via a bus 450 to one or more digital cores 420, which may include one or more cores and/or microcontrollers that act as processing units of the integrated circuit. In turn, digital cores 420 may couple to clock generators 430 which may provide one or more phase locked loops or other clock generator circuitry to generate various clocks for use by circuitry of the IC.

As further illustrated, IC 400 further includes power circuitry 440, which may include one or more voltage regulators, including a voltage regulator 445 as described herein. Additional circuitry may be present depending on particular implementation to provide various functionality and interaction with external devices. Such circuitry may include interface circuitry 460 which provides a digital communication interface with additional circuitry (such as a memory, to couple to IC 400 via a link 495. IC 400 also may include security circuitry 470 to perform wireless security techniques.

In addition, as shown in FIG. 4, transceiver circuitry 480 may be provided to enable transmission and receipt of wireless signals, e.g., according to one or more of a local area or wide area wireless communication scheme, such as Zigbee, Bluetooth, IEEE 802.11, IEEE 802.15.4, cellular communication or so forth. As shown, transceiver circuitry 480 includes multiple transceiver circuits 485₁₋ₙ, to communicate according to multiple wireless communication protocols. Understand while shown with this high level view, many variations and alternatives are possible.

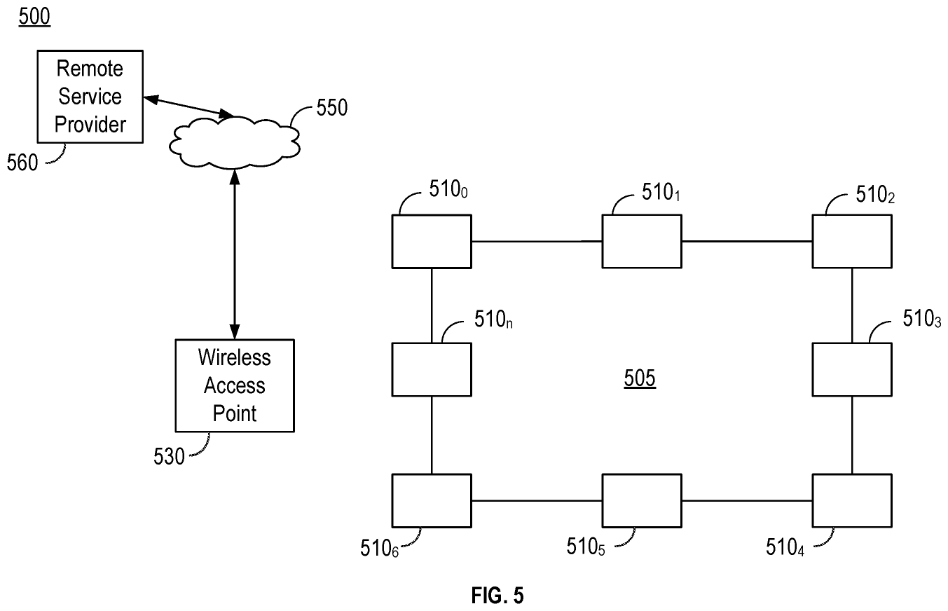

ICs such as described herein may be implemented in a variety of different devices such as wireless stations, IoT devices or so forth. Referring now to FIG. 5, shown is a high level diagram of a network in accordance with an embodiment. As shown in FIG. 5, a network 500 includes a variety of devices, including wireless stations including smart devices such as IoT devices, access points and remote service providers, which may leverage embodiments for powering a PA with a regulated voltage in a manner to reduce memory effect, based at least in part on radio activity as described herein.

In the embodiment of FIG. 5, a wireless network 505 is present, e.g., in a building having multiple wireless devices 510₀₋ₙ. As shown, wireless devices 510 couple to an access point 530 that in turn communicates with a remote service provider 560 via a wide area network 550, e.g., the internet. Understand while shown at this high level in the embodiment of FIG. 5, many variations and alternatives are possible.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
an operational amplifier (opamp) to amplify a difference between a reference voltage and a feedback voltage and output a bias signal based on the difference;
a replica device coupled to the opamp, the replica device having a gate terminal to receive the bias signal; and
an output stage coupled to the replica device and to output a regulated voltage, the output stage comprising a pass device and a plurality of feedback devices coupled to the pass device, wherein a selected number of the plurality of feedback devices are to be enabled based at least in part on an output power level of a power amplifier, the power amplifier to receive the regulated voltage.

2. The apparatus of claim 1, wherein the power amplifier comprises a plurality of slices, the selected number of the plurality of feedback devices based at least in part on a number of the plurality of slices to be enabled.

3. The apparatus of claim 1, further comprising a bias circuit comprising the opamp and the replica device, the replica device to replicate a feedback device of the plurality of feedback devices.

4. The apparatus of claim 3, wherein the replica device comprises a first terminal coupled to a voltage divider, the voltage divider to provide the feedback voltage to the opamp, and a third terminal coupled to a reference voltage node via a resistor.

5. The apparatus of claim 1, further comprising a controller to enable the selected number of the plurality of feedback devices based at least in part on a modulation coding scheme (MCS) index for a wireless transmission by the power amplifier.

6. The apparatus of claim 5, wherein the controller comprises a lookup table, the controller to obtain a control code based at least in part on the output power level and send the control code to selectively enable or disable each of the plurality of feedback devices.

7. The apparatus of claim 1, wherein each of the plurality of feedback devices comprises:
a first terminal coupled to the pass device;
a gate terminal coupled to receive the bias signal; and
a third terminal coupled to a first switch of a plurality of first switches, the first switch to enable the corresponding feedback device based on a bit of the control code.

8. The apparatus of claim 7, wherein the output stage further comprises:
a first current source coupled to the pass device;
a third device coupled to the first current source; and
a second current source coupled to the third device, the third device switchably coupled to a selected one or more of the plurality of feedback devices.

9. The apparatus of claim 7, wherein each of the plurality of first switches is further coupled, at an inter-switch node, to a second switch of a plurality of second switches, wherein the third device is coupled to the inter-switch node.

10. The apparatus of claim 9, wherein each of the plurality of second switches is further coupled to a third current source of a plurality of third current sources.

11. The apparatus of claim 1, wherein the apparatus comprises a voltage regulator for the power amplifier, the voltage regulator to provide analog memory effect compensation, the pass device coupled to the output node without a compensation capacitor.

12. The apparatus of claim 11, wherein the power amplifier is to operate without dynamic digital pre-distortion.

13. A method comprising:
determining, in a controller of a wireless device, an output power level for a wireless transmission to be output via a power amplifier of the wireless device;
based at least in part on the output power level, determining a number of output stage feedback slices of a voltage regulator to be enabled; and
configuring the number of output stage feedback slices of the voltage regulator to couple to an output node of the voltage regulator, the output node to provide a regulated voltage to the power amplifier.

14. The method of claim 13, further comprising causing a corresponding current source of each of the number of output stage feedback slices to be coupled to the output node of the voltage regulator to provide a load current for the power amplifier.

15. The method of claim 13, further comprising:
amplifying, in an operational amplifier (opamp) of the voltage regulator, a difference between a feedback voltage and a reference voltage;
outputting a bias signal based on the difference; and
providing the bias signal to a corresponding feedback device of each of the number of output stage feedback slices.

16. The method of claim 13, further comprising providing the regulated voltage to the power amplifier with a bandwidth sufficient to operate the power amplifier without digital memory effect compensation.

17. A system comprising:
a digital circuit to generate a digital message;
a digital-to-analog converter (DAC) to convert the digital message to an analog signal;
a mixer to upconvert the analog signal to a radio frequency (RF) signal;
a power amplifier coupled to the mixer to amplify the RF signal and output an amplified RF signal, the power amplifier comprising a plurality of slices to be individually controlled to output the amplified RF signal at a selected power level; and
a voltage regulator coupled to the power amplifier, the voltage regulator to provide a regulated voltage to the power amplifier at a current level sufficient for the selected power level, the voltage regulator comprising:
a bias circuit comprising an operational amplifier (opamp) to amplify a difference between a reference voltage and a feedback voltage and output a bias signal based on the difference; and
an output stage coupled to the bias circuit and to output the regulated voltage, the output stage comprising a pass device and a plurality of feedback devices coupled to the pass device, wherein a selected number of the plurality of feedback devices are to be enabled based at least in part on the selected power level and to receive the bias signal.

18. The system of claim 17, further comprising a controller coupled to the voltage regulator, wherein the controller is to provide, based at least in part on the selected power level, a control code to cause the selected number of the plurality of feedback devices to be enabled.

19. The system of claim 17, wherein the power amplifier comprises a multi-slice power amplifier to operate with an error vector magnitude of at least minus 45 decibels, and wherein the power amplifier is to operate without dynamic digital memory effect compensation.

20. The system of claim 17, wherein the voltage regulator is to receive a supply voltage, wherein when the supply voltage is less than a threshold, the voltage regulator is to operate in a bypass mode in which the output stage is to operate as a low resistance switch to pass the supply voltage.
